(19) United States
(12) Patent Application Publication
(10) Pub. No.: US 2025/0185393 A1
(43) Pub. Date: Jun. 5, 2025

(54) METHODS AND SYSTEMS FOR FABRICATION OF INFRARED TRANSPARENT WINDOW WAFER WITH INTEGRATED ANTI-REFLECTION GRATING STRUCTURES

(71) Applicant: DRS Network & Imaging Systems, LLC, Melbourne, FL (US)

(72) Inventor: Thomas Schimert, Midlothian, TX (US)

(73) Assignee: DRS Network & Imaging Systems, LLC, Melbourne, FL (US)

(21) Appl. No.: 18/530,107

(22) Filed: Dec. 5, 2023

Related U.S. Application Data
(60) Provisional application No. 63/430,957, filed on Dec. 7, 2022.

(51) Int. Cl. H01L 27/146; G01J 5/20; G02B 1/118; H01L 23/26; H01L 23/544

(52) U.S. Cl. CPC H10F 39/804; G01J 5/20; H01L 23/26; H01L 23/544; H10F 39/024; H10F 39/806; G01J 2005/204; G02B 1/118; H01L 2223/54426

(57) ABSTRACT

A method of fabricating an IR transparent window wafer with integrated AR grating structures includes providing a handle wafer having a first surface and a second surface opposite the first surface, providing a device wafer including a single crystal silicon layer disposed on an oxide layer, the single crystal silicon layer having a planar side and the oxide layer having a bonding side that is opposite the planar side, forming AR grating structures in a first portion of the first surface of the handle wafer, bonding the bonding side of the oxide layer to the first surface of the handle wafer, and etching a recess in the planar side of the single crystal silicon layer to: remove the buried oxide layer, form a plurality of recess walls, and expose the AR grating structures in the first portion of the first surface of the handle wafer.

### CROSS REFERENCE TO RELATED APPLICATIONS

This application claims priority to U.S. Provisional Patent Application No. 63/430,957, entitled “Methods and Systems for Fabrication of Infrared Transparent Window Wafer with Integrated Anti-Reflection Grating Structures,” filed on Dec. 7, 2022, the disclosure of which is hereby incorporated by reference in its entirety for all purposes.

The following regular U.S. patent applications (including this one) are being filed concurrently, and the entire disclosure of the other application is hereby incorporated by reference into this application for all purposes:
U.S. patent application Ser. No. ______, filed on Dec. 5, 2023, entitled “ENHANCED AREA GETTER ARCHITECTURE FOR WAFER-LEVEL VACUUM PACKAGED UNCOOLED FOCAL PLANE ARRAY;” and
U.S. patent application Ser. No. ______, filed on Dec. 5, 2023, entitled “METHODS AND SYSTEMS FOR FABRICATION OF INFRARED TRANSPARENT WINDOW WAFER WITH INTEGRATED ANTI-REFLECTION GRATING STRUCTURES.”

### BACKGROUND OF THE INVENTION

As photodetector technology continues to develop, new designs can provide vastly improved resolution as compared to technology of the past. Resolution for photodetectors is at least partially determined by the number of pixels in the detector array. Typically, the more pixels in the detector array, the more detail that can be provided during imaging operations. Improved technologies have enabled manufacturing operations to produce pixels of much smaller size in order to maintain the overall form factors of the detector array, while incorporating more pixels to provide the improved resolution.

Despite the progress made in detector arrays, there is a need in the art for improved methods and systems related to detector arrays.

### SUMMARY OF THE INVENTION

In accordance with various aspects of the present disclosure, embodiments of the present disclosure relate to methods and systems for fabrication of infrared transparent window wafer with integrated anti-reflection grating structures.

According to an embodiment of the present invention, a method of fabricating a focal plane array (FPA) structure is provided. The method includes providing a handle wafer having a first surface and a second surface opposite the first surface, providing a device wafer including a single crystal silicon layer disposed on an oxide layer, the single crystal silicon layer having a planar side and the oxide layer having a bonding side that is opposite the planar side, and forming anti-reflection (AR) grating structures in a first portion of the first surface of the handle wafer. The method also includes bonding the bonding side of the oxide layer to the first surface of the handle wafer and etching a recess in the planar side of the single crystal silicon layer to remove the oxide layer, form a plurality of recess walls, and expose the AR grating structures in the first portion of the first surface of the handle wafer.

In some embodiments, the method further includes forming an AR coating on the second surface of the handle wafer; depositing getter material on a second portion of the first surface of the handle wafer, on the plurality of recess walls, or on a third portion of the second surface of the handle wafer; and bonding an FPA wafer to the planar side of the single crystal silicon layer. In various embodiments, the FPA wafer comprises an infrared detector pixel array and an infrared reference pixel. In some embodiments, depositing the getter material is performed using a shadow mask. In various embodiments, the method further includes etching scribe alignment marks in the second surface of the handle wafer. In some embodiments, etching the recess into the planar side of the single crystal silicon layer is performed by dry etching followed by wet etching. In various embodiments, the first portion of the first surface of the handle wafer is disposed inside the plurality of recess walls.

According to another embodiment of the present invention, a method of fabricating an FPA structure is provided. The method includes providing a handle wafer having a first surface and a second surface opposite the first surface, providing a device wafer including a single crystalline silicon layer disposed on an oxide layer, the single crystalline silicon layer having a planar side and the oxide layer having a bonding side that is opposite the planar side, and forming anti-reflection (AR) grating structures in a first portion of the first surface and a second portion of the second surface of the handle wafer. The method also includes bonding the bonding side of the oxide layer to the first surface of the handle wafer and etching a recess in the planar side of the single crystal silicon layer to remove the oxide layer, form a plurality of recess walls, and expose the AR grating structures in the first portion of the first surface of the handle wafer. In some embodiments, the method further includes depositing getter material on a third portion of the first surface of the handle wafer, on the plurality of recess walls, or on a fourth portion of the second surface of the handle wafer and bonding an FPA wafer to the planar side of the single crystal silicon layer.

According to a specific embodiment of the present invention, a method of fabricating an FPA structure is provided. The method incudes providing a handle wafer having a first surface and a second surface opposite the first surface, providing a device wafer including a single crystal silicon layer disposed on an oxide layer, the single crystal silicon layer having a planar side and the oxide layer having a bonding side that is opposite the planar side, and forming first anti-reflection (AR) grating structures in a first portion of the first surface of the handle wafer. The method also includes bonding the bonding side of the oxide layer to the first surface of the handle wafer, forming second AR grating structures in a second portion of the second surface of the handle wafer, and etching a recess in the planar side of the single crystal silicon layer to remove the oxide layer, form a plurality of recess walls, and expose the first AR grating structures in the first portion of the first surface of the handle wafer.

Numerous benefits are achieved by way of the present disclosure over conventional techniques. For example, embodiments of the present disclosure provide methods and systems for fabrication of infrared transparent window wafer with integrated anti-reflection grating structures. Embodiments enable etching of high spatial frequency anti-reflection (AR) grating structures into a first surface of an IR transparent silicon handle wafer prior to bonding the handle wafer to a silicon device wafer to form a silicon on insulator (SOI) structure. The bonded SOI structure can then be used in fabrication of an IR transparent window wafer that is employed in a wafer-level vacuum packaging of uncooled bolometer. The disclosed methods enable fabrication of fine AR grating structures that use sub-micron lithography and etching. Current approaches may form the AR grating structures after formation of a cavity in an SOI structure that includes a handle wafer and thus may encounter a technical challenge of being able to use sub-micron lithography and etching because of the nonplanarity of the surfaces involved after a cavity has been formed. To circumvent this technical challenge, embodiments disclose a fabrication method where the AR grating structures are etched into the handle wafer prior to the bonding step that attaches the silicon device wafer to the handle wafer to form the SOI structure. These and other embodiments of the disclosure, along with many of its advantages and features, are described in more detail in conjunction with the text below and attached figures.

### BRIEF DESCRIPTION OF THE DRAWINGS

Aspects of the present disclosure will now be described more fully hereinafter with reference to the accompanying drawings, which are intended to be read in conjunction with both this summary, the detailed description and any preferred and/or particular embodiments specifically discussed or otherwise disclosed. The various aspects may, however, be embodied in many different forms and should not be construed as limited to the embodiments as set forth herein; rather, these embodiments are provided by way of illustration only and so that this disclosure will be thorough and complete and will fully convey the full scope to those skilled in the art.

FIGS. 1A-1C illustrate a wafer-level vacuum packaging process for uncooled, bolometer-based, focal plane arrays according to embodiments of the disclosure.

FIG. 2 is a cross-sectional view of a focal plane array assembly according to an embodiment of the disclosure.

FIG. 3 shows an isometric view of a window die with anti-reflection (AR) grating structures according to an embodiment of the disclosure.

FIG. 4A illustrates a cross-sectional view of a window die with AR grating structures on both surfaces according to embodiments of the disclosure.

FIG. 4B is a graph showing long wave infrared (LWIR) transmittance and reflectance through the window die of FIG. 4A according to an embodiment of the disclosure.

FIG. 5 is a cross-sectional view of a focal plane array assembly with AR grating structures on the first surface of the handle die and an AR coating on the second surface of the handle die, according to an embodiment of the disclosure.

FIG. 6 is a cross-sectional view of a focal plane array assembly with AR grating structures on both the first and second surfaces of the handle die, according to an embodiment of the disclosure.

FIGS. 7A-7C illustrate a method of fabricating a focal plane array assembly with AR grating structures on the first surface of the handle die according to an embodiment of the disclosure.

FIG. 8 shows a simplified flowchart illustrating a method of fabricating a focal plane array assembly with AR grating structures according to an embodiment of the disclosure.

FIG. 9 is a cross-sectional view of a window die with AR grating structures on both sides of the handle wafer according to an embodiment of the disclosure.

### DETAILED DESCRIPTION OF SPECIFIC EMBODIMENTS

The described embodiments relate generally to focal plane array (FPA) devices. More particularly, embodiments of the present disclosure provide methods and systems for fabrication of infrared transparent window wafer with integrated anti-reflection grating.

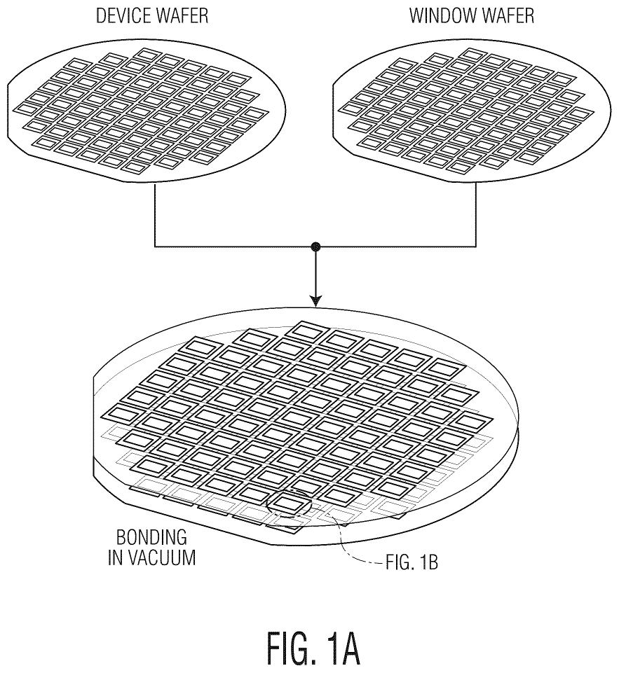

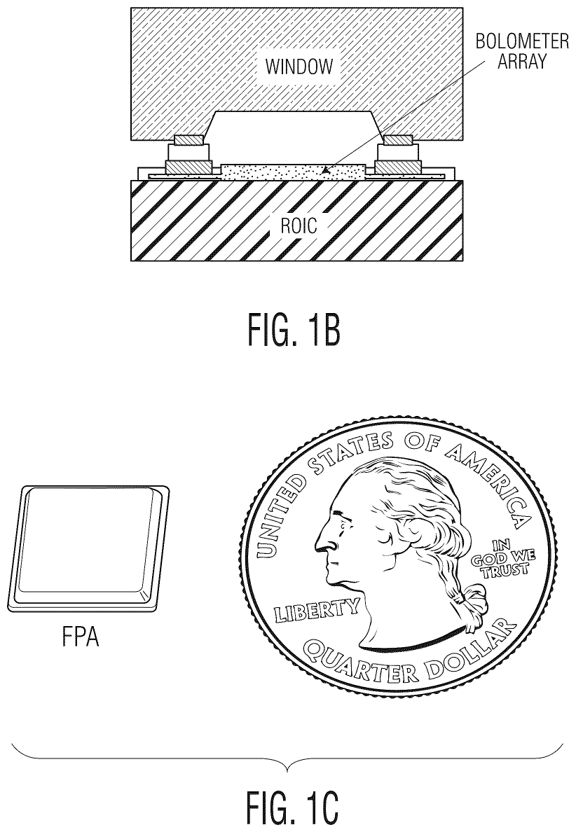

FIGS. 1A-1C illustrate a wafer-level vacuum packaging (WLVP) process for uncooled, bolometer-based, focal plane arrays (FPAs) according to embodiments of the disclosure. In the illustrated embodiment, a solder ring is placed around each die on the FPA wafer with a corresponding seal ring on the mating window wafer. The FPA wafer and window wafer can be aligned and bonded in a vacuum environment. After wafer bonding, slots are sawed in the window wafer to gain access to probe pads on the FPA wafer, thereby enabling post-bond, wafer-scale radiometric testing of vacuum packaged FPAs. Wafer-level vacuum packaging can provide a relatively low size, low weight, and low cost solution for packaging uncooled FPAs.

Modern bolometer-based uncooled infrared (IR) imaging FPAs may thermally isolate the bolometer pixel from the environment to maximize a temperature change of the bolometer pixel induced by infrared scene flux incident on the pixel. A temperature-dependent resistive transducer can detect the scene-induced temperature change through a change in resistance. The temperature-dependent resistive transducer can be made from, but not limited to, vanadium oxide (VOx) or amorphous silicon (a-Si). An array of bolometer pixels addressed by a readout integrated circuit (ROIC) chip allows the bolometer-based, uncooled infrared imaging FPA to image the scene. Thermal isolation of the bolometer pixel can be achieved using relatively long, low thermal conductivity legs that electrically connect the bolometer transducer to an underlying ROIC. In order to achieve relatively high sensitivity, the array of bolometer pixels can be vacuum packaged to reduce or eliminate thermal conductance due to gas molecules in the package. A package vacuum of less than 10 mTorr is maintained to reduce or eliminate the effect of gas thermal conduction in the package.

To maximize transmitted scene radiation through an IR transparent silicon window in the spectral band of interest, such as the long wavelength infrared (LWIR) spectral band that is nominally 7.5 μm to 13.5 μm, anti-reflection (AR) coatings can be deposited on both surfaces of the window.

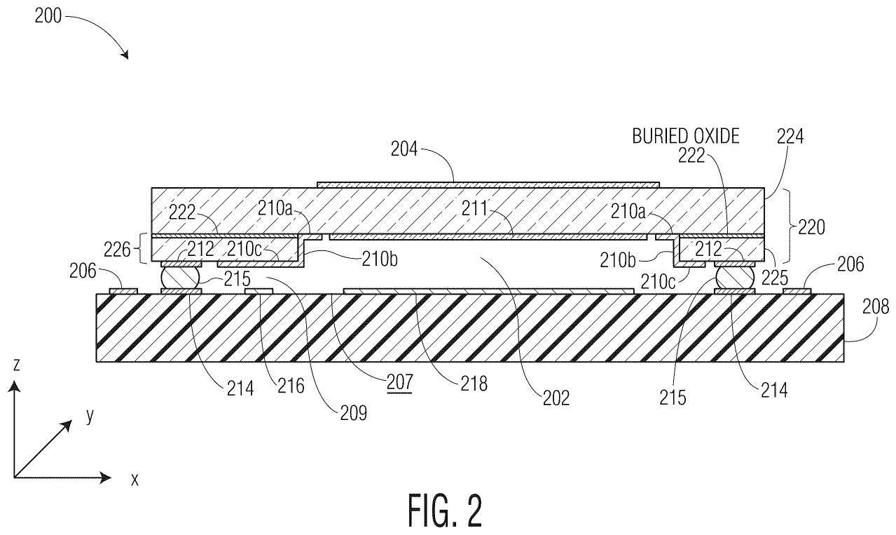

FIG. 2 is a cross-sectional view of a focal plane array (FPA) assembly according to an embodiment of the disclosure. FIG. 2 shows a cross-sectional view of an FPA assembly 200 with deposited AR coatings on both surfaces of a window die. The FPA assembly 200 can include a window die 220 and a device die 208. The window die 220 can be bonded to the device die 208 by solder joints 215. The device die 208 can include an infrared detector pixel array 218 disposed on a first surface 207 of the device die 208 and an optically blind infrared pixel array 216 disposed on the first surface 207. The device die 208 can further include solder ring metallizations 214. Solder joints 215 can be formed on the solder ring metallizations 214. The device die 208 may include bond pads 206 disposed on the first surface 207 of the device die 208. The bond pads 206 can be used for forming connections to a semiconductor package. The bond pads 206 can be used to electrically connect to the ROIC, address the ROIC to bias and run the ROIC, as well as to read out the electrical signal output from the infrared detector pixel array 218.

The window die 220 can include a handle die 224 and a device die 226. In some embodiments, a thickness of the handle die 224 can be, for example, 600 μm, while a thickness of the device die 226 can be, for example, 200 μm. The device die 226 can include a single crystal silicon layer 225 disposed on a buried oxide layer 222. In some embodiments, a thickness of the buried oxide layer 222 can be, for example, 1 to 2 μm. The buried oxide layer 222 can be bonded to a bonding side surface of the handle die 224. The window die 220 can include a recess 202. The recess 202 may be formed by etching of the device die 226, where the etching also removes the buried oxide layer 222. The device die 226 may include solder ring metallizations 212. The solder joints 215 can be connected to the solder ring metallizations 212.

A cavity 209 can be formed adjacent the recess 202 and positioned between the device die 208 and the window die 220. The cavity 209 and the recess 202 can be vacuum environments. Getter material can be formed on a bonding side surface of the handle die 224 in regions 210a, on die wall surfaces in regions 210b, and on a second side surface of the device die 226 in regions 210c. In this way, getter material surface area can be increased or maximized within the cavity 209 and the recess 202 because the die wall surfaces are used to form getter material. The recess 202 can be made deeper or shallower by adjusting the thickness of the device die 226. Optical aperture permitting, the recess depth can be increased, thereby increasing available getter area on the die wall surfaces in regions 210b. In some embodiments, a perimeter of the recess 202, and thus the size of the recess 202, is reduced to enable formation of getter on all sides of the recess 202. In this way, the volume of the recess 202 is reduced while enabling additional getter material in the volume defined by the recess 202. Thus, embodiments of the present invention utilize the getter material to not only form an optical blocking structure above the infrared pixel array 216, but to also form an increased amount of getter material and an increased amount of getter area in the vacuum environment by depositing getter material both on die wall surfaces in region 210b and/or on the bonding side surface of the handle die 224 in regions 210a. It should be noted that embodiments of the present invention reduce the perimeter of recess 202 and, thereby, reduce the volume corresponding to the recess 202, which is typically undesirable since this reduction in volume reduces the volume to getter surface area ratio. However, since getter material is formed on die wall surfaces in region 210b, the volume to getter surface area ratio can be maintained or increased despite the reduced volume. As will be evident to one of skill in the art, the amount of getter material that can be formed on the bonding side surface of the handle die 224 in regions 210a is limited by the optical aperture that is needed to receive infrared radiation passing through the handle die 224 to the infrared detector pixel array 218. One of ordinary skill in the art would recognize many variations, modifications, and alternatives.

As illustrated in FIG. 2, the height of cavity 209, measured along the z-direction, can be much smaller than the height of recess 202, also measured along the z-direction. As discussed above, the height of recess 202 can be related to the thickness of the device die 226, for example, 200 μm, whereas the height of cavity 209 can be related to the thickness of solder ring metallizations 212, solder joints 215, and solder ring metallizations 214, which can be on the order of 10 μm. Thus, blocking of light that would otherwise reach the infrared pixel array 216 is facilitated by embodiments of the present invention since positioning the getter material on regions 210c closer to the infrared pixel array 216 results in more effective light blocking performance. At the same time, the height of recess 202 is independent of the height of cavity 209, enabling a larger volume for a given surface area, which is desirable to achieve a low pressure (e.g., 10 mTorr) environment.

A first anti-reflection (AR) coating 204 may be formed on a planar side of the handle die 224. A second AR coating 211 may be formed on the bonding side surface of the handle die 224. The handle die 224 can be transparent to infrared radiation in order to enable infrared radiation to pass through the handle die 224 and impinge on the infrared detector pixel array 218. The AR coatings can be formed on both the planar and bonding sides of the handle die 224 in regions open to the collecting aperture for scene flux incident on the infrared detector pixel array 218. In some embodiments, the anti-reflection layer can be a deposited AR coating, for example, a multi-layer dielectric stack. In various embodiments, the AR layers can be formed from high spatial frequency, anti-reflection gratings etched into the handle die surfaces.

Because the height of the recess 202 is on the order of 200 μm, the second AR coating 211 can be close enough to the infrared detector pixel array 218 that the second AR coating 211 is within the depth of field of the imaging optics. As a result, any defects present in the second AR coating 211 can adversely impact the imaging performance of the FPA assembly, resulting in image artifacts.

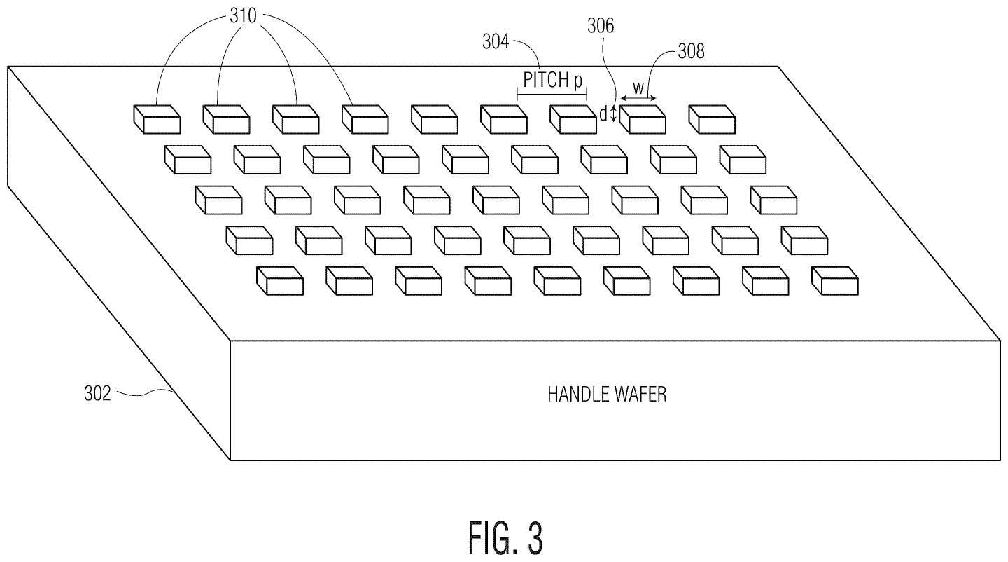

FIG. 3 shows an isometric view of a window die with anti-reflection (AR) grating structures according to an embodiment of the disclosure. In the illustrated embodiment, a silicon handle wafer 302 is shown with a two-dimensional binary grating structure that includes a plurality of square pillars 310 having a width 308 (w), a periodically spaced pitch 304 (p), and a depth distance 306 (d). The square pillars are formed of silicon and the depth distances are defined by etching into the silicon. The illustrated two-dimensional binary grating is a high spatial frequency diffraction grating with a pitch p<λ_{edge}/n_{Si} where λ_{edge} is the shortest wavelength in the 7.5 μm to 13.5 μm LWIR spectral band of interest, i.e., λ_{edge}=⁷0.5 μm, and n_{Si} ˜3.42 is the refractive index of silicon in the LWIR spectral band. In a high spatial frequency grating with a pitch p<λ_{edge}/n_{Si}, the only propagating modes for the diffraction grating within the LWIR spectral band are the zeroth order transmitted mode T₀ and the zeroth order reflected mode R₀. In some embodiments, the energy in the zeroth order reflected mode R₀ is reduced or minimized, thereby increasing or maximizing transmittance in the zeroth order transmitted mode T₀. In an imaging system, there is a cone of radiation incident on the silicon window due to the focusing optics of the system. In this case, the zeroth order transmitted mode T₀ and the zeroth order reflected mode R₀ can be maintained as the only propagating modes for all angles of incidence subtended by the cone of radiation.

AR grating structure examples for two different pitches are described in Table 1:

TABLE 1

| | | |
|---|---|---|
| Si pillar pitch p (μm) | 1.85 | 1.75 |
| Square Si pillar width w (μm) | 1.33 | 1.26 |
| Trench width between Si pillars (μm) | 0.52 | 0.49 |

The AR grating structure with pitch p=1.85 μm can suppress higher order diffractive modes up to an angle of incidence of ˜39° off normal incidence. The AR grating structure with pitch p=1.75 μm can suppress higher order diffractive modes up to an angle of incidence of ˜60° off normal incidence. Because both these grating structures suppress higher order diffraction over a wide angle of incidence ranges, they can be used as anti-reflection structures.

To maximize transmittance of IR radiation across the interface from air, with refractive index nₐᵢᵣ=1, into silicon, or similarly from silicon to air, the effective refractive index of the AR grating n_{eff} must be:

$${n}_{eff} = \sqrt{{n}_{Si}}$$

where n_{Si}˜3.42 is the refractive index of silicon in the LWIR spectral band. Thus, an AR grating structure may have a refractive index of:

$${n}_{eff} = \sqrt{3.42} ∼ 1.84 .$$

Both AR grating structure examples of FIG. 3 and Table 1 (pitch p=1.85 μm and Si pillar w˜1.33 μm; or pitch p=1.75 μm and the Si pillar w˜1.26 μm) can be used such that n_{eff}˜1.84 for the etched grating region. As discussed above, the exemplary AR grating structure with pitch p=1.85 μm can suppress higher order diffractive modes and function as an AR grating within the LWIR spectral band up to an angle of incidence of ˜39° off normal incidence. The example with AR grating structure with pitch p=1.75 μm can suppress higher order diffractive modes and function as an AR grating within the LWIR spectral band up to an angle of incidence of ˜60° off normal incidence.

Further, a depth distance 306 (d) can be determined as disclosed below. The depth distance 306 (d) can be determined by using the effective refractive index of the grating, n_{eff}, and by the quarter-wave thickness condition that minimizes reflected radiation off the surface. For a selected wavelength λₚₑₐₖ, within the LWIR spectral band, the quarter-wave minimum reflectance d is:

$$d = {λ}_{peak} / ( 4 {n}_{eff} ) .$$

For example, if the peak transmittance is selected to be at λₚₑₐₖ=9 μm, then the optimal AR grating depth distance d etched into the silicon window is given by:

$$d ∼ 9 / ( 4 * 1.84 ) ∼ 1.2 μm .$$

In both AR grating structure examples of Table 1, the depth distance d˜1.2 μm. This depth distance is etched into silicon and can serve as an antireflection structure for both the air-to-Si or Si-to-air (or vacuum) interfaces.

Although square pillars 310 are illustrated in FIG. 3, embodiments of the present invention are not limited to this particular geometry and other shapes, including a round shape, an oval shape, a complementary silicon ridge structure with square trenches, or the like can be utilized and are included within the scope of the present invention. One of ordinary skill in the art would recognize many variations, modifications, and alternatives.

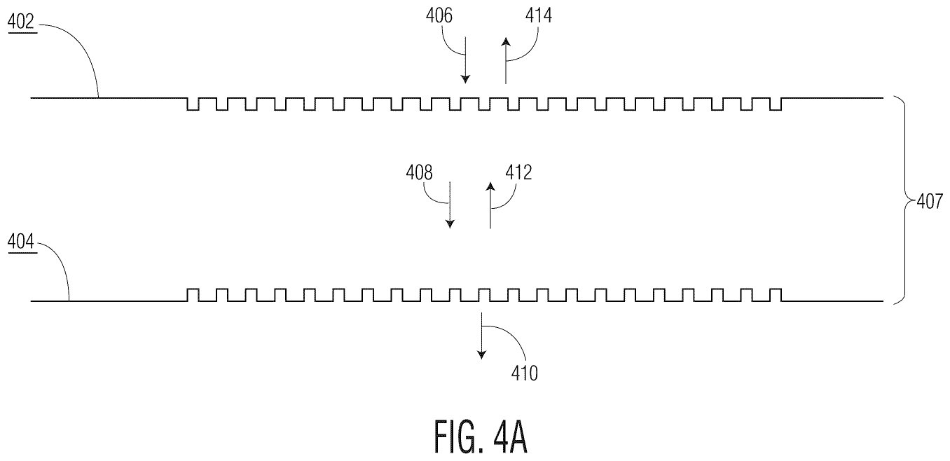

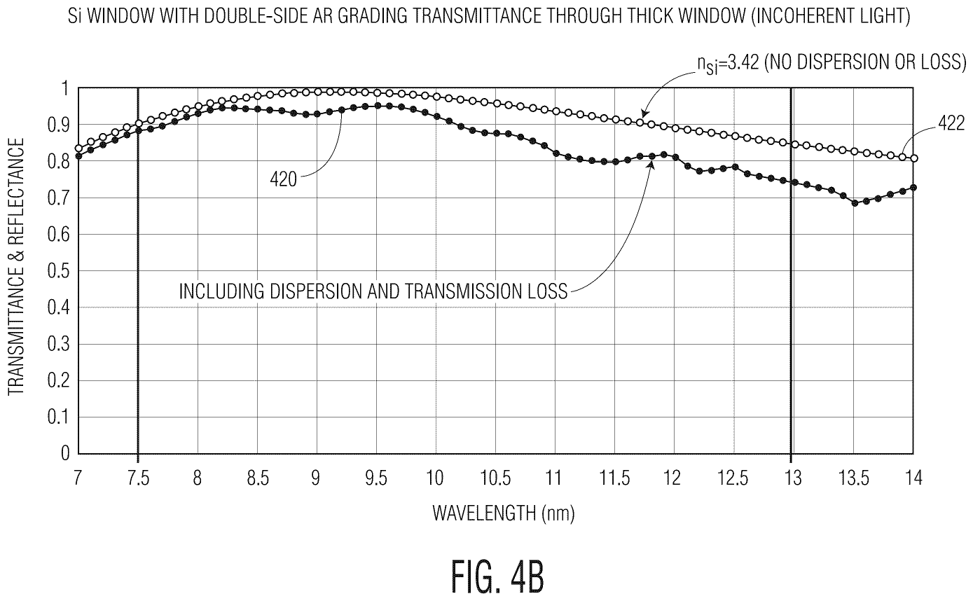

FIG. 4A illustrates a cross-sectional view of a window die with AR grating structures on both surfaces according to embodiments of the disclosure. The window die 407 can be formed from silicon and can have an index of n_{Si}=3.42. The window die 407 can have a first surface 402 and a second surface 404 opposite the first surface 402. The AR grating structures of the first surface can have n_{eff}=1.84 μm and d=1.2 μm, and the AR grating structures of the second surface can have n_{eff}=1.84 μm and d=1.2 μm. Arrow 406 represents incident LWIR radiation in air (n=1), while arrow 414 represents reflected LWIR radiation from the first surface 402. Arrows 408 and 412 represent LWIR radiation zeroth order modes propagating in the window die 407. Arrow 410 represents incident LWIR radiation exiting the window die 407 into air or into vacuum.

FIG. 4B is a graph showing LWIR transmittance and reflectance through the window die of FIG. 4A according to an embodiment of the disclosure. FIG. 4B shows the modelled LWIR transmittance at normal incidence through a silicon window die with optimally designed AR grating structures with etched depth distance of 1.2 μm. Graph 420 shows transmittance including dispersion and transmission loss through silicon, while graph 422 shows transmittance with no dispersion or transmission loss through silicon. As shown in FIG. 4B, a peak transmittance is observed at λₚₑₐₖ=9 μm. The transmittance for a lossless silicon window with n_{Si} ˜3.42, (i.e., ignoring any dispersion loss) exhibits 100% transmittance at λₚₑₐₖ=9 μm and average transmittance of ˜94% across the 7.5-13.5 μm spectral band. In practice, the IR transparent silicon used for infrared window applications may exhibit some dispersion loss, which, when included, can reduce the average transmittance to ˜86% across the 7.5-13.5 μm spectral band for a silicon window die thickness of 600 μm. For comparison, for a bare silicon window, with no anti-reflection structure on the surfaces, an average transmittance across the 7.5-13.5 μm spectral band is significantly lower, at 54% ignoring dispersion loss, and 49% including dispersion loss, as shown in Table 2.

TABLE 2

| | Average LWIR | |
|---|---|---|
| | transmittance | Average LWIR |
| | with AR grating | transmittance |
| | structures on both | with no AR grating |
| | the first surface and | structures or |
| | the second surface | coatings |
| Si window die ignoring | 94% | 54% |
| dispersion and loss | | |
| Si window die including | 86% | 49% |
| dispersion and loss in 600 μm | | |
| thick IR transparent silicon | | |

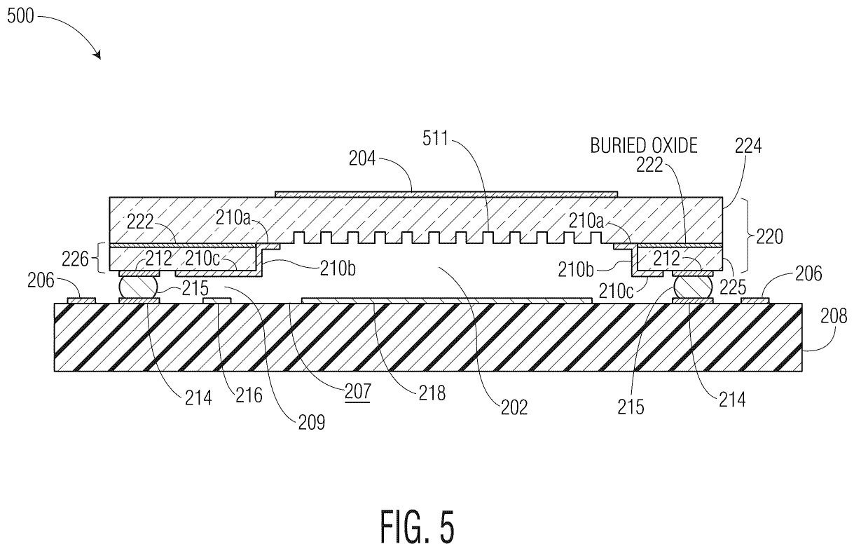

FIG. 5 is a cross-sectional view of a focal plane array (FPA) assembly with AR grating structures on the first surface of the handle die and an AR coating on the second surface of the handle die, according to an embodiment of the disclosure. FIG. 5 shows a cross-sectional view of an FPA assembly 500 that is similar to FPA assembly 200 except the first surface of the handle die 224 includes AR grating structures 511, while the second surface of the handle die 224 includes the first AR coating 204. The inventor has determined that fabricating the AR grating structures 511 with sub-micron features in the recess 202 presents a number of manufacturing challenges. Accordingly, embodiments of the present invention provide methods and systems to fabricate the AR grating structures 511 in the recess 202 with desired optical properties.

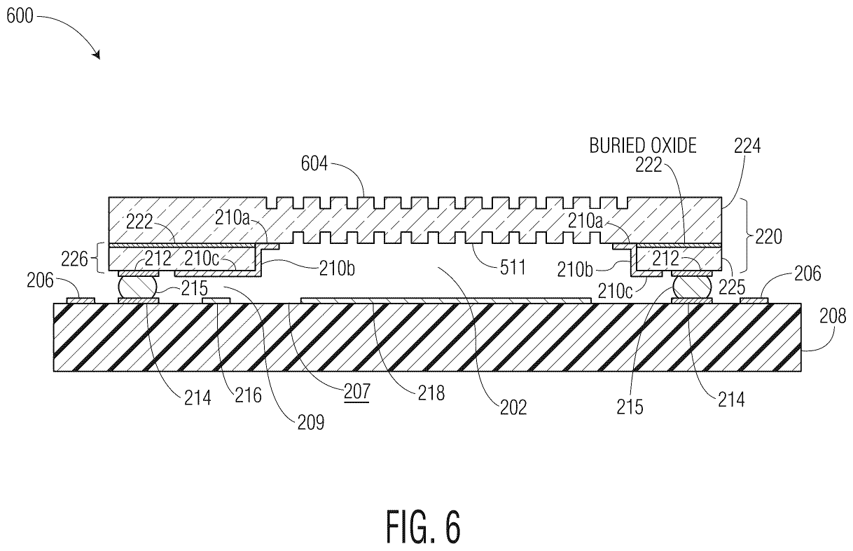

FIG. 6 is a cross-sectional view of a focal plane array assembly with AR grating structures on both the first and second surfaces of the handle die, according to an embodiment of the disclosure. The disclosure provided in relation to FIGS. 2 and 5 is applicable to FIG. 6 as appropriate. FIG. 6 shows a cross-sectional view of an FPA assembly 600 that is similar to FPA assembly 200 except both the first and second surfaces of the handle die 224 include AR grating structures 511 and 604, respectively.

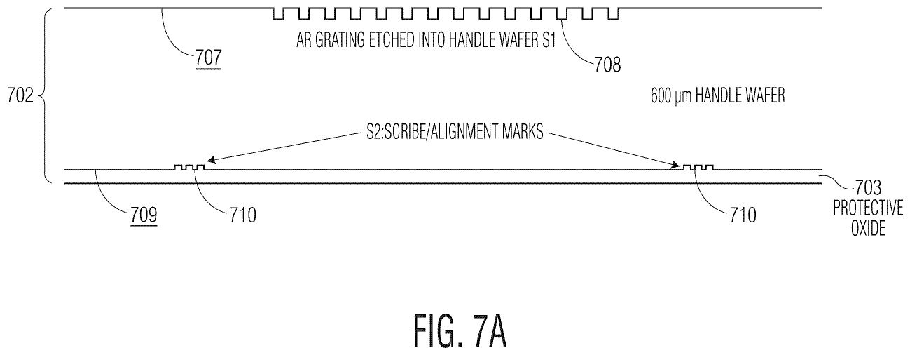

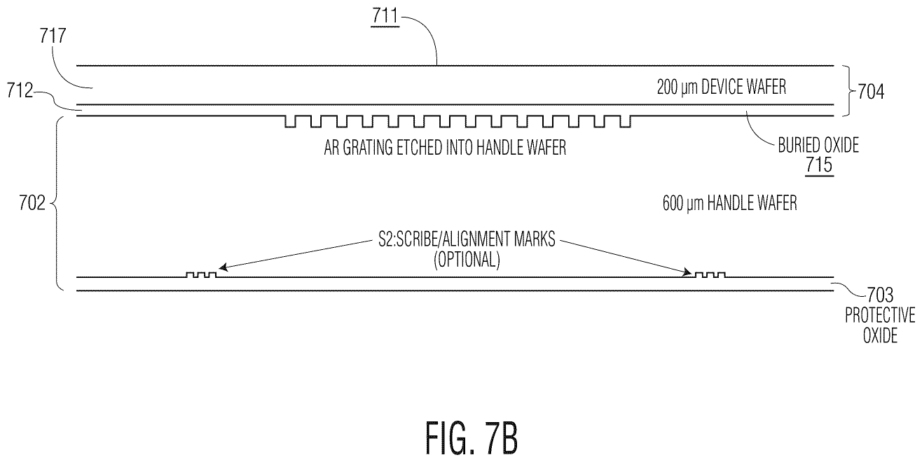

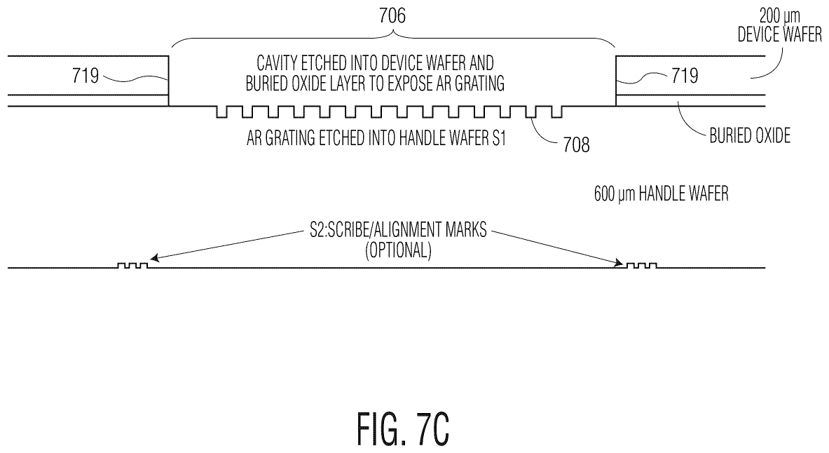

FIGS. 7A-7C illustrate a method of fabricating a focal plane array assembly with AR grating structures on the first surface of the handle die according to an embodiment of the disclosure. In the illustrated embodiment, the method includes etching high spatial frequency AR grating structures into a first surface of an IR transparent silicon handle wafer prior to bonding the handle wafer to a silicon device wafer and, thereby, forming a silicon on insulator (SOI) structure including the high spatial frequency AR grating structures. The bonded structure with integrated high spatial frequency AR grating structures can then be used during the fabrication of an IR transparent window wafer that is employed in a wafer-level vacuum packaging process for an uncooled bolometer.

The disclosed method enables fabrication of sub-micron AR grating structures that use lithography and etching processes. In contrast with approaches that form the AR grating structures after formation of a cavity in an SOI structure, and thus may encounter the technical challenge of being unable to use sub-micron lithography and etching because of the nonplanarity of the surfaces involved after a cavity has been formed, embodiments of the present invention form the AR grating structures prior to formation of the cavity in the SOI structure.

Accordingly, to circumvent this technical challenge, embodiments disclose a fabrication method as shown in FIGS. 7A-7C in which the AR grating structures are etched into the handle wafer prior to the bonding step that attaches the silicon on insulator wafer (i.e., the single crystal silicon device layer and the buried oxide) to the handle wafer to form the SOI structure. As will be evident to one of skill in the art, the fabrication of the SOI structure can utilize oxide growth on either the handle wafer and/or the single crystal silicon wafer during the SOI structure fabrication process.

As shown in FIG. 7A, a handle wafer 702 is provided having a first surface 707 and a second surface 709. AR grating structures 708 can be etched into the first surface 707 of the handle wafer 702. At this point in the fabrication process, the first surface 707 is planar, allowing faithful sub-micron patterning and etching of the AR grating structures 708 into the first surface 707 of the handle wafer 702. The disclosed method further includes etching scribe alignment marks 710 into the second surface 709 of the handle wafer 702. The scribe alignment marks can allow registration between patterns on the first surface and the second surface in subsequent fabrication steps. In some embodiments, the AR grating structures 708 are fabricated prior to the fabrication of the scribe alignment marks 710.

In some embodiments, a protective oxide layer 703 can be formed on the second surface 709. The protective oxide layer 703 can have a thickness of, for example, 1-2 μm. In various embodiments, the handle wafer 702 can have a thickness of, for example, 600 μm and can be made of IR transparent, low dispersion loss silicon.

As shown in FIG. 7B, the handle wafer 702, also referred to as a handle die, and a device wafer 704, also referred to as an SOI wafer, an SOI die, or a device die, can be bonded together to form an SOI structure. The device wafer 704 can have a planar side 711 and a bonding side 715. The device wafer 704 can have a single crystal silicon device layer 717 disposed on a buried oxide layer 712. The bonding side 715 of the device wafer 704 can be bonded to the first surface 707 of the handle wafer 702. In some embodiments, the buried oxide layer can have a thickness of, for example, 1-2 μm. In various embodiments, the device wafer 704 can have a thickness of, for example, 200 μm.

In some embodiments, since oxide growth consumes silicon during the oxide growth process, the buried oxide layer 712 is grown on the bonding side 715 of the single crystal silicon device layer 717 prior to bonding of the device wafer 704 and the handle wafer 702. This process prevents modification of the geometry of the AR grating structures 708 that were previously etched into the first surface 707 of the handle wafer 702. Accordingly, in these embodiments, the single crystal silicon device layer 717 and the buried oxide layer 712 are bonded to the handle wafer 702. It should be noted that the recessed portions of the AR grating structures 708 may not be bonded to the handle wafer 702. However, the inventors have determined that the protrusions of the AR grating structure 708, as well as other portions of first surface 707 of the handle wafer 702, provide enough bonding area to form a suitable bond for the SOI structure.

In other embodiments, the AR grating structures 708 are fabricated in the first surface 707 of the handle wafer 702 and the buried oxide is subsequently grown on the first surface 707 of the handle wafer 702. Since this oxide growth process will consume a portion of the AR grating structures 708, the AR grating structures are initially fabricated with dimensions larger than the final dimensions that result after growth and subsequent removal of the buried oxide as discussed in relation to FIG. 7C below. One of ordinary skill in the art would recognize many variations, modifications, and alternatives.

As shown in FIG. 7C, a recess 706 can be etched in the planar side 711 of the single crystal silicon device layer 717 to remove the buried oxide layer 712, form recess walls 719 and expose the AR grating structures 708. In some embodiments, the recess 706 can have a depth of, for example, 200 μm. The etching of the recess can be performed by dry etching followed by wet etching, during which the buried oxide layer 712 is removed. In various embodiments, the fabrication method further includes depositing getter material on a third portion of the first surface of the handle wafer, on the plurality of recess walls, or on a fourth portion of the second surface of the handle wafer, and bonding an FPA wafer to the planar side of the single crystal silicon layer.

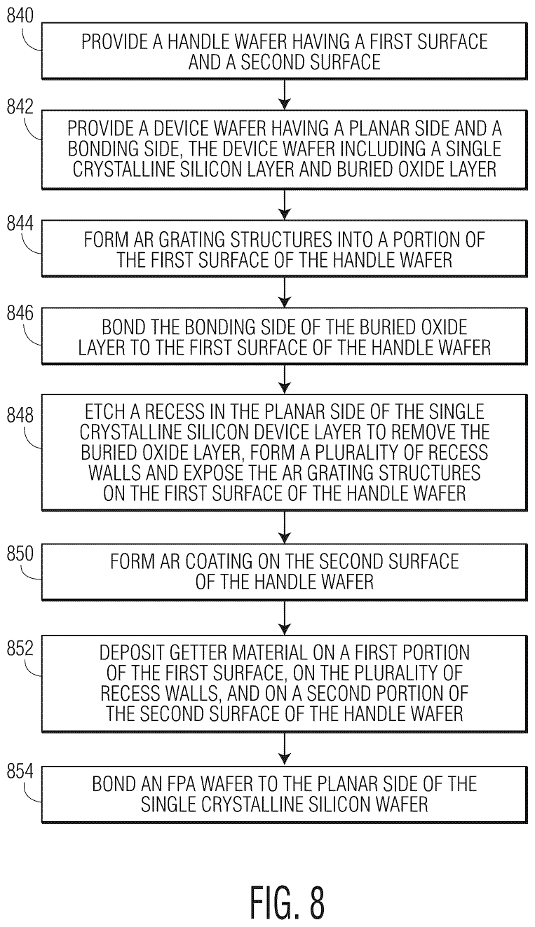

FIG. 8 is a simplified flowchart illustrating a method of fabricating an FPA structure with AR grating structures according to embodiments of the disclosure. As illustrated in FIG. 8, the method of fabricating the FPA structure includes providing a handle wafer having a first surface and second surface (840). The method also includes providing a device wafer having a planar side and a bonding side (842), the device wafer including a single crystalline silicon layer and an oxide layer. The method further includes forming AR grating structures in a first portion of the first surface of the handle wafer (844).

Additionally, the method includes bonding the bonding side of the device wafer to the first surface of the handle wafer (846). The method further includes etching a recess in the planar side of the device wafer to remove a portion of the oxide layer, forming a plurality of recess walls, and exposing the AR grating structure on the first surface of the handle wafer (848). As illustrated in FIG. 7C, the recess 706 passes through a portion of the single crystal silicon device layer 717 and through a portion of the oxide layer 712. Further, the method includes forming an anti-reflection (AR) coating on the second surface of the handle wafer (850). Moreover, the method includes depositing getter material on a second portion of the first surface, on the plurality of recess walls, and/or on a third portion of the second surface of the handle wafer (852). Additionally, the method includes bonding an FPA wafer (e.g., an ROIC substrate) to the planar side of the single crystalline silicon wafer (854).

It should be appreciated that the specific steps illustrated in FIG. 8 provide a particular method of fabricating an FPA structure with AR grating structures according to an embodiment of the disclosure. Other sequences of steps may also be performed according to alternative embodiments. For example, alternative embodiments of the disclosure may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. One of ordinary skill in the art would recognize many variations, modifications, and alternatives.

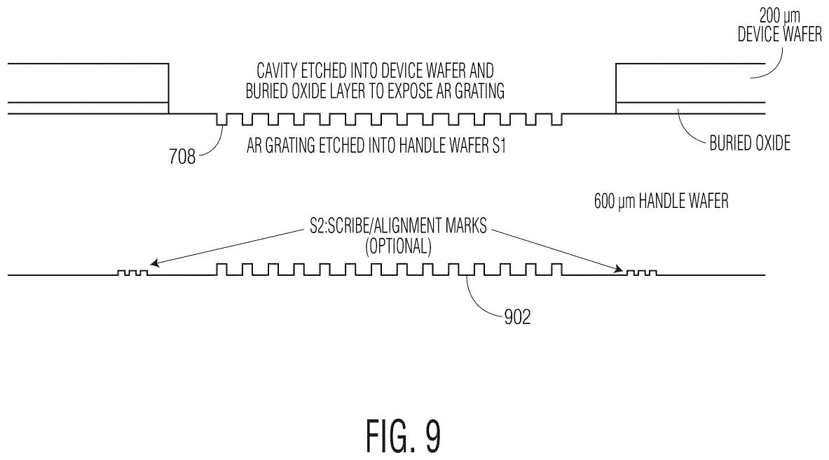

In some embodiments, the AR grating structures can be formed on both surfaces of the handle wafer. FIG. 9 illustrates a window wafer fabricated with AR grating structures 708 on the first surface 707 of the handle wafer and AR grating structures 902 on the second surface 709 of the handle wafer. The AR grating structures 708 and 902 can be both formed at the start of the fabrication similar to FIG. 7A. In some embodiments, the AR grating structure 902 can be formed after the SOI wafer 704 has been bonded to the handle wafer 702 because the second surface 709 of the handle wafer 702 can remain relatively planar through the fabrication process. In various embodiments, the AR grating structure 902 can be formed after the recess 706 has been formed.

Various examples of the present disclosure are provided below. As used below, any reference to a series of examples is to be understood as a reference to each of those examples disjunctively (e.g., “Examples 1-4” is to be understood as “Examples 1, 2, 3, or 4”).

Example 1 is a method of fabricating a focal plane array (FPA) structure, the method comprising: providing a handle wafer having a first surface and a second surface opposite the first surface; providing a device wafer including a single crystal silicon layer disposed on an oxide layer, the single crystal silicon layer having a planar side and the oxide layer having a bonding side that is opposite the planar side; forming anti-reflection (AR) grating structures in a first portion of the first surface of the handle wafer; bonding the bonding side of the oxide layer to the first surface of the handle wafer; and etching a recess in the planar side of the single crystal silicon layer to: remove the oxide layer; form a plurality of recess walls; and expose the AR grating structures in the first portion of the first surface of the handle wafer.

Example 2 is the method of fabricating the FPA structure of example 1, further comprising: forming an AR coating on the second surface of the handle wafer; depositing getter material on a second portion of the first surface of the handle wafer, on the plurality of recess walls, or on a third portion of the second surface of the handle wafer; and bonding an FPA wafer to the planar side of the single crystal silicon layer.

Example 3 is the method of fabricating the FPA structure of example(s) 1-2, wherein the FPA wafer comprises an infrared detector pixel array and an infrared reference pixel.

Example 4 is the method of fabricating the FPA structure of example(s) 1-2, wherein depositing the getter material is performed using a shadow mask.

Example 5 is the method of fabricating the FPA structure of example 1, further comprising etching scribe alignment marks in the second surface of the handle wafer.

Example 6 is the method of fabricating the FPA structure of example 1, wherein etching the recess into the planar side of the single crystal silicon layer is performed by dry etching followed by wet etching.

Example 7 is the method of fabricating the FPA structure of example 1, wherein the first portion of the first surface of the handle wafer is disposed inside the plurality of recess walls.

Example 8 is a method of fabricating a focal plane array (FPA) structure, the method comprising: providing a handle wafer having a first surface and a second surface opposite the first surface; providing a device wafer including a single crystalline silicon layer disposed on an oxide layer, the single crystalline silicon layer having a planar side and the oxide layer having a bonding side that is opposite the planar side; forming anti-reflection (AR) grating structures in a first portion of the first surface and a second portion of the second surface of the handle wafer; bonding the bonding side of the oxide layer to the first surface of the handle wafer; and etching a recess in the planar side of the single crystal silicon layer to: remove the oxide layer; form a plurality of recess walls; and expose the AR grating structures in the first portion of the first surface of the handle wafer.

Example 9 is the method of fabricating the FPA structure of example 8, further comprising: depositing getter material on a third portion of the first surface of the handle wafer, on the plurality of recess walls, or on a fourth portion of the second surface of the handle wafer; and bonding an FPA wafer to the planar side of the single crystal silicon layer.

Example 10 is the method of fabricating the FPA structure of example(s) 8-9, wherein the FPA wafer comprises an infrared detector pixel array and an infrared reference pixel.

Example 11 is the method of fabricating the FPA structure of example(s) 8-9, wherein depositing the getter material is performed using a shadow mask.

Example 12 is the method of fabricating the FPA structure of example 8, wherein further comprising etching scribe alignment marks in the second surface of the handle wafer.

Example 13 is the method of fabricating the FPA structure of example 8, wherein etching the recess into the planar side of the single crystal silicon layer is performed by dry etching followed by wet etching.

Example 14 is the method of fabricating the FPA structure of example 8, wherein the first portion of the first surface of the handle wafer is disposed inside the plurality of recess walls.

Example 15 is a method of fabricating a focal plane array (FPA) structure, the method comprising: providing a handle wafer having a first surface and a second surface opposite the first surface; providing a device wafer including a single crystal silicon layer disposed on an oxide layer, the single crystal silicon layer having a planar side and the oxide layer having a bonding side that is opposite the planar side; forming first anti-reflection (AR) grating structures in a first portion of the first surface of the handle wafer; bonding the bonding side of the oxide layer to the first surface of the handle wafer; forming second AR grating structures in a second portion of the second surface of the handle wafer; and etching a recess in the planar side of the single crystal silicon layer to: remove the oxide layer; form a plurality of recess walls; and expose the first AR grating structures in the first portion of the first surface of the handle wafer.

Example 16 is the method of fabricating the FPA structure of example 15, further comprising: depositing getter material on a third portion of the first surface of the handle wafer, on the plurality of recess walls and on a fourth portion of the second surface of the handle wafer; and bonding an FPA wafer to the planar side of the single crystal silicon layer.

Example 17 is the method of fabricating the FPA structure of example(s) 15-16, wherein the FPA wafer comprises an infrared detector pixel array and an infrared reference pixel.

Example 18 is the method of fabricating the FPA structure of example(s) 15-16, wherein depositing the getter material is performed using a shadow mask.

Example 19 is the method of fabricating the FPA structure of example 15, further comprising etching scribe alignment marks in the second surface of the handle wafer.

Example 20 is the method of fabricating the FPA structure of example 15, wherein etching the recess into the planar side of the single crystal silicon layer is performed by dry etching followed by wet etching.

The names for the various structures can be interchangeable. For example, the device wafer may be referred to as an FPA wafer and the silicon on insulator wafer may be referred to as a device wafer or an SOI structure.

One of ordinary skill in the art will appreciate that other modifications to the apparatuses and methods of the present disclosure may be made for implementing various applications of the methods and systems for fabrication of infrared transparent window wafer with integrated anti-reflection grating without departing from the scope of the present disclosure.

The examples and embodiments described herein are for illustrative purposes only. Various modifications or changes in light thereof will be apparent to persons skilled in the art. These are to be included within the spirit and purview of this application, and the scope of the appended claims which follow.

What is claimed is:

1. A method of fabricating a focal plane array (FPA) structure, the method comprising:
providing a handle wafer having a first surface and a second surface opposite the first surface;
providing a device wafer including a single crystal silicon layer disposed on an oxide layer, the single crystal silicon layer having a planar side and the oxide layer having a bonding side that is opposite the planar side;
forming anti-reflection (AR) grating structures in a first portion of the first surface of the handle wafer;
bonding the bonding side of the oxide layer to the first surface of the handle wafer; and
etching a recess in the planar side of the single crystal silicon layer to:
remove the oxide layer;
form a plurality of recess walls; and
expose the AR grating structures in the first portion of the first surface of the handle wafer.

2. The method of claim 1, further comprising:
forming an AR coating on the second surface of the handle wafer;
depositing getter material on a second portion of the first surface of the handle wafer, on the plurality of recess walls, or on a third portion of the second surface of the handle wafer; and
bonding an FPA wafer to the planar side of the single crystal silicon layer.

3. The method of claim 2, wherein the FPA wafer comprises an infrared detector pixel array and an infrared reference pixel.

4. The method of claim 2, wherein depositing the getter material is performed using a shadow mask.

5. The method of claim 1, further comprising etching scribe alignment marks in the second surface of the handle wafer.

6. The method of claim 1, wherein etching the recess into the planar side of the single crystal silicon layer is performed by dry etching followed by wet etching.

7. The method of claim 1, wherein the first portion of the first surface of the handle wafer is disposed inside the plurality of recess walls.

8. A method of fabricating a focal plane array (FPA) structure, the method comprising:
providing a handle wafer having a first surface and a second surface opposite the first surface;
providing a device wafer including a single crystalline silicon layer disposed on an oxide layer, the single crystalline silicon layer having a planar side and the oxide layer having a bonding side that is opposite the planar side;
forming anti-reflection (AR) grating structures in a first portion of the first surface and a second portion of the second surface of the handle wafer;
bonding the bonding side of the oxide layer to the first surface of the handle wafer; and
etching a recess in the planar side of the single crystal silicon layer to:
remove the oxide layer;
form a plurality of recess walls; and
expose the AR grating structures in the first portion of the first surface of the handle wafer.

9. The method of claim 8, further comprising:
depositing getter material on a third portion of the first surface of the handle wafer, on the plurality of recess walls, or on a fourth portion of the second surface of the handle wafer; and
bonding an FPA wafer to the planar side of the single crystal silicon layer.

10. The method of claim 9, wherein the FPA wafer comprises an infrared detector pixel array and an infrared reference pixel.

11. The method of claim 9, wherein depositing the getter material is performed using a shadow mask.

12. The method of claim 8, further comprising etching scribe alignment marks in the second surface of the handle wafer.

13. The method of claim 8, wherein etching the recess into the planar side of the single crystal silicon layer is performed by dry etching followed by wet etching.

14. The method of claim 8, wherein the first portion of the first surface of the handle wafer is disposed inside the plurality of recess walls.

15. A method of fabricating a focal plane array (FPA) structure, the method comprising:
providing a handle wafer having a first surface and a second surface opposite the first surface;
providing a device wafer including a single crystal silicon layer disposed on an oxide layer, the single crystal silicon layer having a planar side and the oxide layer having a bonding side that is opposite the planar side;
forming first anti-reflection (AR) grating structures in a first portion of the first surface of the handle wafer;
bonding the bonding side of the oxide layer to the first surface of the handle wafer;
forming second AR grating structures in a second portion of the second surface of the handle wafer; and
etching a recess in the planar side of the single crystal silicon layer to:
remove the oxide layer;
form a plurality of recess walls; and
expose the first AR grating structures in the first portion of the first surface of the handle wafer.

16. The method of claim 15, further comprising:
depositing getter material on a third portion of the first surface of the handle wafer, on the plurality of recess walls and on a fourth portion of the second surface of the handle wafer; and
bonding an FPA wafer to the planar side of the single crystal silicon layer.

17. The method of claim 16, wherein the FPA wafer comprises an infrared detector pixel array and an infrared reference pixel.

18. The method of claim 16, wherein depositing the getter material is performed using a shadow mask.

19. The method of claim 15, further comprising etching scribe alignment marks in the second surface of the handle wafer.

20. The method of claim 15, wherein etching the recess into the planar side of the single crystal silicon layer is performed by dry etching followed by wet etching.
